(19) United States
(12) Patent Application Publication
(10) Pub. No.: US 2013/0195140 A1
(43) Pub. Date: Aug. 1, 2013

(54) Temperature Sensor

(71) Applicants: Vittorio Scardaci, Dublin (IE); Graeme Scott, Kidare (IE); Richard Coull, Dundalk (IE); Lorraine Byrne, Dublin (IE); Jonathan Coleman, Dublin (IE)

(72) Inventors: Vittorio Scardaci, Dublin (IE); Graeme Scott, Kidare (IE); Richard Coull, Dundalk (IE); Lorraine Byrne, Dublin (IE); Jonathan Coleman, Dublin (IE)

(21) Appl. No.: 13/363,018

(22) Filed: Jan. 31, 2012

(51) Int. Cl. G01K 7/00; H01L 21/66; B82Y 15/00; B82Y 40/00

(52) U.S. Cl. 374/163; 438/17; 374/E07.018; 977/742; 977/842

(57) ABSTRACT

The present invention relates to a temperature sensor comprising a network of carbon nanotubes, wherein an electrical resistance of the network of carbon nanotubes is indicative of a temperature to which the network of carbon nanotubes has been exposed. The present invention further relates to a time temperature indicator and a method of manufacturing a temperature sensor.

### FIELD

The present invention relates to a temperature sensor and a method of making such a sensor. The present invention further relates to a time temperature indicator.

### BACKGROUND

Temperature sensors are known. A time temperature indicator (TTI) is an example of a device which uses a temperature sensor to indicate a temperature history of the TTI In known TTIs, the temperature sensing may be based on a physical change, such as diffusion, a chemical reaction, an electrochemical change or an enzymatic reaction; such reactions/changes may yield a colour change, the extent of which depends on the temperature the TTI was exposed to and the period of time the TTI was exposed to that temperature. TTIs may be used in association with an item to indicate the temperature history of the item. For example, in a food supply chain a TTI may be used to indicate if a perishable food product has been exposed to a greater temperature than desired. If the TTI indicates that such exposure has occurred, the food product can be checked for quality and possible spoiling.

### BRIEF DESCRIPTION OF THE DRAWINGS

FIGS. 1 to 4 illustrate graphs of electrical resistance behaviour of carbon nanotube networks according to examples of the present invention; and

FIGS. 5 and 6 illustrate schematically an example of a temperature sensor according to an example of the present invention.

### DETAILED DESCRIPTION

In the present invention, a network of carbon nanotubes is used for sensing temperature. An electrical resistance of the network of carbon nanotubes is indicative of a temperature to which the network of carbon nanotubes has been exposed.

An example of a method of manufacturing an example of a network of carbon nanotubes in accordance with the present invention will now be described.

Firstly, single walled carbon nanotubes in the form of a dry powder, for example Iljin SWCNT from Hanwha Nanotechnology, 3F Shine Bldg., 423-1 Cheongcheon-dong, Bupyeong-gu, Incheon,403-030 Korea, are dispersed uniformly in a liquid which is for example water or an organic solvent, for example N-methylpyrrolidone (NMP) supplied by Sigma-Aldrich, 3050 Spruse Street, St Louis, Mo., 63103, Mo., USA. For example, milligram of the dry powder is dispersed in 1 millilitre of solvent. A surfactant for example sodium dodecylsulphate (SDS) is used to stabilise the dispersion of the carbon nanotubes in the liquid. For example, 1 wt % as surfactant concentration in water may be used. Alternative surfactants may be used, for example sodium dodecylbenzenesulphonate (SDBS), sodium cholate (SC), sodium deoxycholate (SDC) or cetyl trimethylammonium bromide (CTAB). Dispersing of the carbon nanotubes in the liquid with surfactant is known and may for example be performed using ultrasonication, for example with 5 minutes of tip sonication, then 60 minutes of bath sonication, and then 5 further minutes of tip sonication. The tip sonicator may for example be a Misonix 3000 Sonicator at the 12W setting and the bath sonicator may be a Branson 3510 model.

After the ultrasonication the dispersion is centrifuged for example for 2 hours at 10,000 relative centrifugal force (RCF). The supernatant of the centrifuged dispersion is deposited on a substrate using for example spray coating yielding a film with a thickness of for example 100 nanometers or less. Alternatively the supernatant may be deposited using vacuum filtration, dip coating, ultrasonic spray or inkjet printing. The substrate may be flexible or rigid, and transparent or non-transparent. In an example, the substrate is formed of polyethyleneterephthalate (PET).

After the deposition of the carbon nanotubes on the substrate, residual surfactant is rinsed from the deposited carbon nanotubes using water. This may be done simply by dipping the deposited network in a water bath for a few minutes. This yields a network of carbon nanotubes.

After forming the network of carbon nanotubes, a treatment of the network of carbon nanotubes may determine the electrical resistance behaviour of the network of carbon nanotubes when exposed to a predetermined temperature. For example, such a treatment may be a doping treatment. Such a doping treatment may include doping the network of carbon nanotubes with an acid, for example nitric acid.

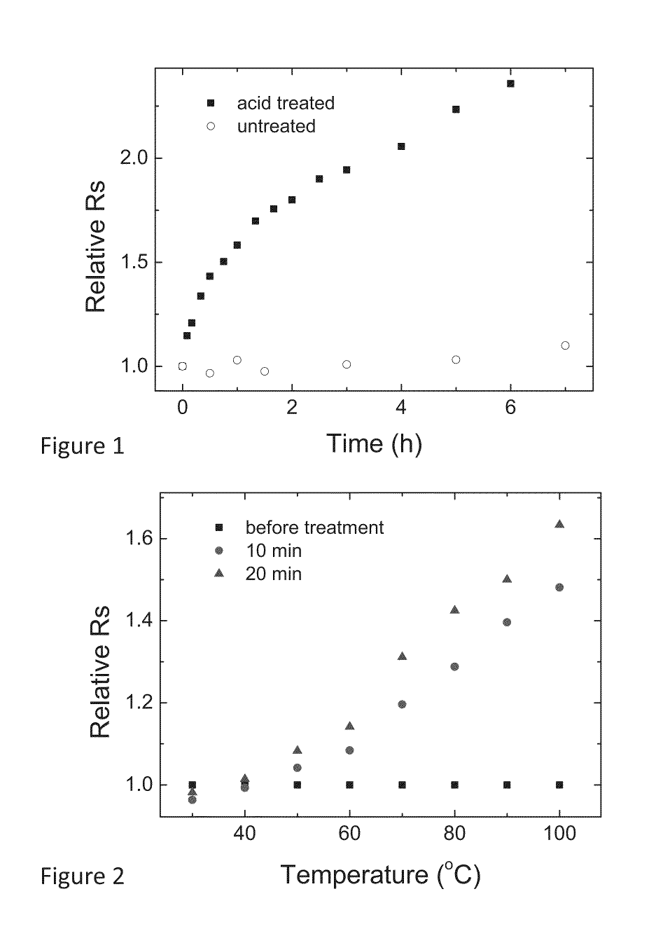

FIG. 1 is a graph illustrating an example of the effect of doping the network of carbon nanotubes with nitric acid. In this example the deposited network of carbon nanotubes was treated for 15 minutes with concentrated (12M) nitric acid at room temperature and then rinsed thoroughly with water. The resulting doped network was then left to stabilise for 24 hours at room temperature. Then, the network of carbon nanotubes was exposed to a temperature of 100 degrees Celsius for different periods of time. The electrical resistance (also referred to herein as the resistance) of the network of carbon nanotubes (also referred to herein as the network) was measured for each of the periods of time the network was exposed to 100 degrees Celsius, once the network had cooled to room temperature.

FIG. 1 illustrates the electrical resistance (Relative Rs) of the network as a function of time in hours (h) upon exposure to 100 degrees Celsius. The black square markers in FIG. 1 illustrate the electrical resistance behaviour of the nitric acid doped network whereas the circular markers illustrate the electrical resistance behaviour of the network without the nitric acid doping. As can be seen, for the doped network, the electrical resistance of the network increases over time when exposed to 100 degrees Celsius. Without being bound to any theory, it is believed this increase in electrical resistance, a decrease in electrical condivity of the network, is caused by exposure to the predetermined temperature causing de-doping of the network.

The electrical resistance of the doped network after exposure to a predetermined temperature, in this case 100 degrees Celsius for a certain period of time, does not decrease when the network is cooled below the predetermined temperature. This means the resistance of the network may be measured after exposure of the network to the predetermined temperature. Thus, the electrical resistance behaviour of the network of carbon nanotubes may be capable of indicating, exposure of the network of carbon nanotubes to a predetermined temperature. The electrical resistance behaviour of the network of carbon nanotubes may therefore be capable of indicating a period of time that the network of carbon nanotubes has been exposed to a predetermined temperature.

Using the electrical resistance measurement of the network after exposure to the predetermined temperature, the network may therefore be used to sense temperature. The examples of networks of carbon nanotubes described above may therefore be used in a temperature sensor.

The electrical resistance behaviour of the network of carbon nanotubes may be resettable. In other words, the electrical resistance of the network may be reset, recovered, for example after the network has been exposed to a predetermined temperature such as 100 degrees Celsius. After resetting, the network may therefore be used again to sense a different temperature. The electrical resistance behaviour of the network may be reset by a doping treatment, for example the doping with nitric acid described previously. It is to be appreciated that the electrical resistance of the network may be reset to the same resistance as previously, or to a different resistance, by appropriate selection of the doping conditions such as the period of time the network is exposed to the nitric acid and/or the concentration of the nitric acid. As the skilled person would understand, the conditions of the treatment to reset the resistance may depend on the resistance of the network at the start of the reset treatment.

FIG. 2 illustrates the electrical resistance behaviour of three networks of carbon nanotubes, when exposed to different predetermined temperatures for a fixed time (in this case 30, 40, 50, 60, 70, 80, 90 and 100 degrees Celsius). The three networks are prepared in the same manner described previously except that the network referred to using the plot line of square markers is the network before the doping treatment. The plot line of circular markers indicates the nitric acid doped network when exposed to the predetermined temperature for 10 minutes and the plot line of triangular markers indicates the nitric acid doped network when exposed to the predetermined temperature for 20 minutes. As FIG. 2 shows, the longer the doped. network is exposed to the predetermined temperature, the higher the resistance change of the network. The undoped network shows no increase in resistance. The resistance measurements in FIG. 2 are normalised to starting resistance values; hence the relative resistance (relative Rs) is plotted.

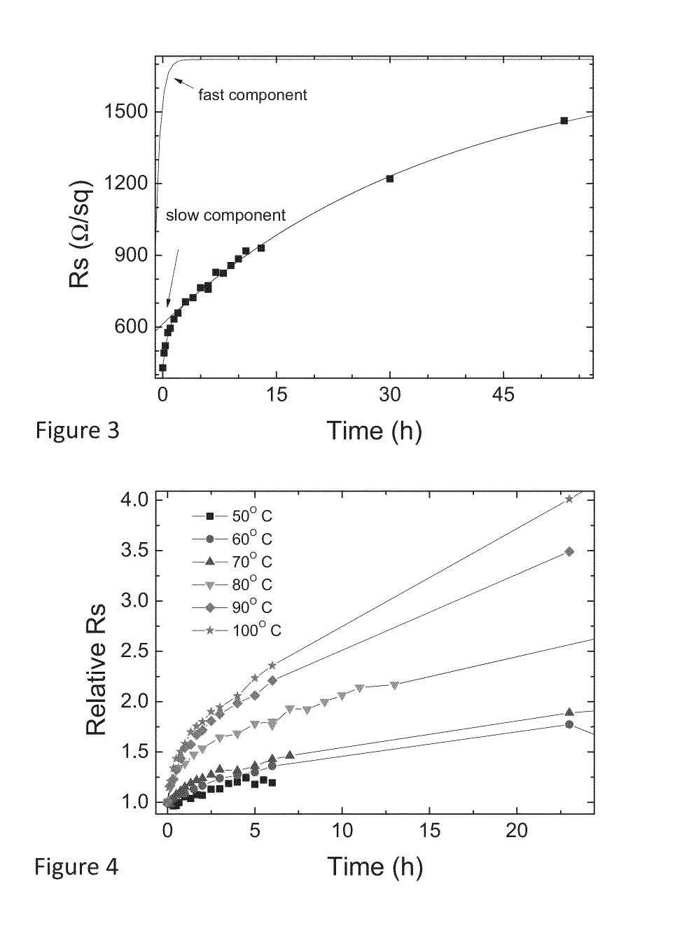

FIG. 3 is a graph of a representative resistance (Rs) vs time response for exposure of an example network to 80 degrees Celsius. It is clear the resistance increases over time, The response is fitted by a double exponential curve, with a fast and a slow component as illustrated. In this example such a resistance change response applies to all resistance data acquired in the 50-100 degrees Celsius temperature range.

FIG. 4 is a graph showing the effect of time and temperature on the resistance of different samples of an example of a nitric acid doped carbon nanotube network. The resistance measurements are normalised to starting resistance values; hence the relative resistance (relative Rs) is plotted. As illustrated, the rate of change of resistance over time depends on the temperature the network is exposed to. Thus, nitric acid doped carbon nanotube networks may be used in a temperature sensor and a time temperature indicator, as described in further detail below.

As described above, a nitric acid doped network of carbon nanotubes may exhibit an increase in resistance upon exposure to a predetermined temperature. This behaviour may be used to sense temperature. Examples of a temperature sensor using such a network of carbon nanotubes will now be described.

In one example of the present invention, a temperature sensor is provided which comprises a network of carbon nanotubes, where an electrical resistance of the network of carbon nanotubes is indicative of a temperature to which the network of carbon nanotubes has been exposed. The electrical resistance behaviour of the network of carbon nanotubes may be determined by a treatment, for example a doping treatment such as the nitric acid doping treatment described above. Accordingly, in an example of the present invention, a temperature sensor comprises a nitric acid doped network of carbon nanotubes, such as a nitric acid doped carbon nanotube network described above.

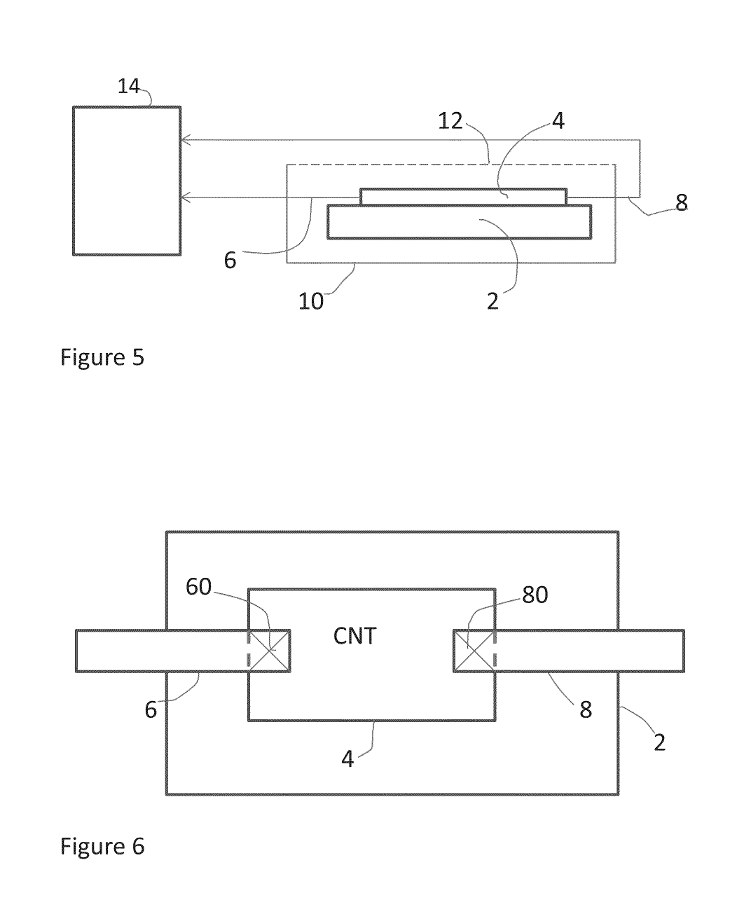

FIG. 5 illustrates a cross section and FIG. 6 illustrates a plan view of a temperature sensor according to an example of the present invention. A temperature sensor is a device which detects a temperature to which the sensor is exposed. The temperature sensor comprises a substrate 2 on which is a network of carbon nanotubes (CNT). In this example the network of carbon nanotubes is applied on the substrate as a film 4 and is one of the examples of a nitric acid doped network of carbon nanotubes described previously. The method of forming such a network may be one of the methods described previously. The film may for example be 100 nanometres thick or less.

In the present example, electrical conductors 6 and 8 are connected to spaced apart zones 60, 80 (shown in FIG. 6) of the network. The conductors 6 and 8 may make contact with silver paste contacts, or any other suitable conductor compatible with carbon nanotubes and the substrate, deposited on the spaced apart zones 60, 80 of the film.

In this example, a housing 10 protects the film, substrate and conductors but allows air to enter the housing, thus exposing the film to the ambient air temperature. The housing may mechanically protect the film from damage which may change its resistance. The housing may for example have holes in a wall 12 above the film. A sheet (not shown) porous to air may cover the holes inside the housing. An example of a suitable sheet is a thin film with micro perforations. The housing may be of plastics or any other suitable material which mechanically protects the film. Plastics may be chosen because they are also electrically insulative. Depending on the construction of the housing, the housing may affect the temperature the network is exposed to compared with the ambient temperature. In some examples the measuring device may be calibrated accordingly. In other examples, it is to be appreciated that the temperature sensor may not comprise the housing and/or the porous sheet.

In this example a measuring device 14 is connected to the network of carbon nanotubes, via the conductors 6, 8, and is configured to measure the electrical resistance or the electrical conductivity of the network of carbon nanotubes. The resistance of the film may be measured using the known four point measurement which eliminates contributions from contact resistance: see for example: http://en.wikipedia.org/wiki/Four-terminal sensing

A method of manufacture of a temperature sensor according to the present invention includes providing a network of carbon nanotubes; and treating the network of carbon nanotubes to determine an electrical resistance behaviour of the network of carbon nanotubes When exposed to a predetermined temperature. The treating of the network of carbon nanotubes may comprise doping the network of carbon nanotubes for example with an acid such as nitric acid. In further examples, the doping conditions may be different from those described above; for example the period of time of doping the network with nitric acid and/or the concentration of the nitric acid used as a dopant may be different from above. The nitric acid concentration may be 12 molar (M), 1M, or less than 12 M and greater than 1M. A lower concentration than 1M may not yield a satisfactorily doped network. The carbon nanotubes may be single walled tubes or multiwalled tubes or a mixture of single and multiwalled tubes. The carbon nanotubes may be a mixture of metallic and semiconductive tubes. In further examples, it is envisaged that an alternative network of carbon nanotubes may be used in the temperature sensor, which network has an electrical resistance indicative of a temperature to which the network of carbon nanotubes has been exposed to. Such electrical resistance behaviour may be determined by a doping treatment other than doping with nitric acid, or a non doping treatment.

The substrate may be of plastics, ceramic, glass, silicon, paper for example photo-paper, or any other suitable material which is inert to the network. The substrate may be rigid or flexible. The substrate may be transparent. A suitable substrate is PET (polyethylene terephthalate), which is flexible and transparent. The measuring device may be an ohmmeter: such devices are well known.

The electrical resistance, or the electrical conductivity (from which the resistance may be calculated), measured by the measuring device is indicative of a temperature to Which the network of carbon nanotubes has been exposed. For example, by knowing the manufacture method and conditions of the network of carbon nanotubes in the temperature sensor, and the electrical resistance behaviour of the network with temperature, the measured resistance of the network after its exposure to a predetermined temperature may be used to indicate the predetermined temperature the sensor was exposed to. For example, if the period of time of exposing the sensor to a predetermined temperature is known, the graph of FIG. 4 may be used to determine the temperature the network has been exposed to, using the measured resistance of the network. Of course, if the network has not been exposed to the predetermined temperature, for example the network has not been exposed to a temperature greater than 50 degrees Celsius, its lack of resistance change indicates this.

In such examples of the temperature sensor, it is to be appreciated that if the sensor has been exposed to more than one different predetermined temperature, whether or not the period of time of exposure is known, it may not be possible to determine the period of time which the network has been exposed to each temperature for. However, the temperature sensor may nonetheless simply indicate that the network has been exposed to a temperature greater than a desired temperature which desired temperature may be a set threshold temperature such as 50 degrees Celsius. Thus, any temperature above the desired temperature may be considered as the predetermined temperature.

If the temperature sensor is being used to monitor the temperature history of an item of perishable food whilst being transported, for example, the recipient of the food product at the end of the transportation can use the measured resistance given by the measuring device to assess whether the food item has been exposed to an above desirable temperature. If so, the recipient can assess the quality of the food product, if however the measuring device gives a resistance reading which indicates the food product has not been exposed to a greater than desired temperature, the recipient need not assess the quality of the food product.

Alternatively, if the predetermined temperature to which the sensor is exposed is known, the resistance or electrical conductivity of the network may be used to indicate the period of time which the network was exposed to the predetermined temperature.

In further examples of the present invention, the measuring device may be configured to measure the resistance or electrical conductivity of the network over a period of time. If the measuring device is configured to record the resistance or conductivity measurements for a plurality of moments over this period of time, a temperature history of the network may be provided. From this it can be determined whether the network was exposed to a predetermined temperature, and possibly a plurality of different predetermined temperatures, and for how long at each temperature.

In further examples of the present invention, a time temperature indicator (TTI) comprises a temperature sensor described previously. A TTI is a device which provides an indication of the temperature history of the TTI, for example if the network of carbon nanotubes has been exposed to a predetermined temperature. Using a temperature sensor described previously, a TTI may therefore be configured to use the measured resistance or conductivity to indicate whether the network of carbon nanotubes has been exposed to a predetermined temperature. Such an indication may be a visual indication for example a colour change, a yes/no indication or another visual indication of whether exposure to a predetermined temperature has occurred. The extent of the visual change may indicate the extent of exposure to the predetermined temperature. If the measuring device is configured to measure the electrical resistance or conductivity over a period of time, the TTI may indicate a temperature history, for example a plot of the resistance change and/or corresponding temperature change over time, of the network of carbon nanotubes.

A temperature sensor and a time temperature indicator in accordance with the examples described above provide a straightforward method of indicating exposure to a predetermined temperature, obtained using simple and cost effective manufacturing techniques. The electrical resistance behaviour of the network may be configured using appropriate doping conditions, for example, such that the rate of change of resistance with exposure to a predetermined temperature is similar or the same as a rate of degradation or a change of an item, such as a perishable food item, with exposure to the predetermined temperature. A temperature sensor and a TTI may therefore give an accurate indication of the temperature exposure of the item it has been configured for.

As described, above, the electrical resistance behaviour of a network of carbon nanotubes may be reset using a doping treatment for example. A temperature sensor and a TTI in accordance with examples of the present invention may therefore be reset after exposure to a predetermined temperature, for re-use. Depending on the reset conditions of for example doping, the electrical resistance behaviour may be the same or different as the previous resistance behaviour.

The above examples are to be understood as illustrative examples of the invention. Further examples of the invention are envisaged. For example, in further examples, the temperature sensor may not comprise the measuring device, the contacts and/or the housing or porous sheet. In such examples, the resistance may be measured after exposure of the network of carbon nanotubes to a predetermined temperature, by connecting a measuring device temporarily to the network.

It is to be understood that any feature described in relation to any one example may be used alone, or in combination with other features described, and may also be used in combination with one or more features of any other of the examples, or any combination of any other of the examples. Furthermore, equivalents and modifications not described above may also be employed without departing from the scope of the invention, which is defined in the accompanying claims.

1. A temperature sensor comprising a network of carbon nanotubes, wherein an electrical resistance of the network of carbon nanotubes is indicative of a temperature to which the network of carbon nanotubes has been exposed.

2. A temperature sensor according to claim 1, wherein the network of carbon nanotubes has been treated to determine an electrical resistance behaviour of the network of carbon nanotubes when exposed to a predetermined temperature.

3. A temperature sensor according to claim 2, wherein the network of carbon nanotubes has been treated with a doping treatment to determine said electrical resistance behaviour.

4. A temperature sensor according to claim 3, wherein the doping treatment includes doping the network of carbon nanotubes with nitric acid.

5. A temperature sensor according to claim 1, wherein the electrical resistance behaviour of the network of carbon nanotubes is capable of indicating exposure of the network of carbon nanotubes to a predetermined temperature.

6. A temperature sensor according to claim 1, wherein the electrical resistance behaviour of the network of carbon nanotubes is capable of indicating a period of time that the network of carbon nanotubes has been exposed to a predetermined temperature.

7. A temperature sensor according to claim 1 wherein, after exposure of the network of carbon nanotubes to a predetermined temperature, an electrical resistance behaviour of the network of carbon nanotubes is resettable.

8. A temperature sensor according to claim 7, wherein the electrical resistance behaviour is resettable by a doping treatment.

9. A temperature sensor according to claim 8, wherein the doping treatment comprises doping the network of carbon nanotubes with nitric acid.

10. A temperature sensor according to claim 1 comprising a measuring device connected to the network of carbon nanotubes and configured to measure the electrical resistance or the electrical conductivity of the network of carbon nanotubes.

11. A time temperature indicator comprising the temperature sensor of claim 1.

12. A time temperature indicator comprising the temperature sensor of claim 10, the time temperature indicator being configured to use said measured electrical resistance or electrical conductivity to indicate whether the network of carbon nanotubes has been exposed to the predetermined temperature.

13. A time temperature indicator according to claim 12, wherein the measuring device is configured to measure said electrical resistance or said electrical conductivity over a period of time to indicate a temperature history of the network of carbon nanotubes.

14. A method of manufacture of a temperature sensor, including:
providing a network of carbon nanotubes; and
treating the network of carbon nanotubes to determine an electrical resistance behaviour of the network of carbon nanotubes when exposed to a predetermined temperature.

15. A method of manufacture according to claim 14, wherein said treating of the network of carbon nanotubes comprises doping the network of carbon nanotubes or doping the network of carbon nanotubes with nitric acid.
